(19) United States
(12) Patent Application Publication
(10) Pub. No.: US 2014/0043015 A1
(43) Pub. Date: Feb. 13, 2014

(54) ELECTRICAL CONDUCTOR PHASE IDENTIFICATION SYSTEM

(71) Applicants: Harold I. Marsden, Westborough, MA (US); Aaron P. Coolidge, Northborough, MA (US)

(72) Inventors: Harold I. Marsden, Westborough, MA (US); Aaron P. Coolidge, Northborough, MA (US)

(21) Appl. No.: 13/738,094

(22) Filed: Jan. 10, 2013

Related U.S. Application Data
(60) Provisional application No. 61/585,452, filed on Jan. 11, 2012.

(51) Int. Cl. G01R 29/00

(52) U.S. Cl. CPC G01R 29/00
USPC 324/86

(57) ABSTRACT

A system for identifying an electrical phase of three conductors in a three-phase electrical system at an open end is provided. The system includes a transmitter and a receiver unit. The transmitter unit has three current transformers configured to removably couple with one of the three conductors adjacent the transformer. The transmitter unit further having a first communication device configured to transmit a phase identification signal indicating at least one electrical phase detected on one of the three conductors. The receiver unit has a first output lead configured to removably couple at the open end with a first conductor and a second output lead configured to couple with a second conductor. The receiver unit is configured to transmit a trace current onto the first output lead. The receiver further displays phase identification information in response to receiving the phase identification signal.

### CROSS REFERENCE TO RELATED APPLICATIONS (IF APPLICABLE)

The Present application claims priority to U.S. Provisional Application Ser. No. 61/585,452 filed on 11 Jan. 2012, the contents of which are incorporated herein in their entirety.

### BACKGROUND OF THE INVENTION

The subject matter disclosed herein relates to a system for identification of an electrical phase of a cable and more particularly to a system that determines an electrical phase where the cable has either a conductive outer cover or a nonconductive outer cover.

Electrical cables are used in a wide variety of application to transfer a electrical power from one location to another. In some cases, high levels of electrical power need to be transferred requiring the use of particular cables. A variety of types of conductors may be used, such as paper insulated lead covered cable, solid dielectric cable, oil filled pipe type cable or gas-filled insulated cable for example. In three-phase operation, three cables will be used together each carrying a single electrical phase. Over time, a break or open condition may occur in these cables for a variety of reasons such as maintenance, construction or an electrical fault for example. When a break occurs in the cables, it is necessary to identify the phase of each cable prior to reconnecting the ends of the cable.

Identification of the correct phase is important for the proper operation of the power system. The crossing of phases during repairs will result in having to re-work the splice and risk potential failures that could damage the conductors and other equipment in the electrical network.

Before any work can be performed on the conductors, the feeder circuit in the distribution network needs to be identified and protected (grounded) for work. The method of identifying the feeder circuit will depend on how the conductors were damaged. If only one of the conductors is broken, applying a tracing current to the two remaining conductors can identify the feeder circuit. This technique is effective because the remaining conductors provide a return path for the tracer current.

When the fault causes a break in all three conductors, the tracing current method will not be effective since there is no return path. In this case, a spear is applied to the cable shorting all three conductors. This creates a path for the tracing current so that the feeder can be identified. However, the phase of each cable cannot be identified with the spear in place.

Commonly, the identification of the phases and the repairs of the cables are performed by separate personnel: a Splicer who repairs and splices the conductors back together, and a phase identification crew. Separate personnel are used because the tracing method used for identifying the phase requires additional special training. Further, the phase identification crew needs to locate and travel to the transformers located on either side of the section having an open circuit condition. The transformers are grounded, isolating the section having an open circuit condition. The Splicer then prepares the conductors for splicing. The identification crew applies an audio frequency tracing tone to the conductors on the transformer side of the conductor and then travels back to the section having the open circuit condition. The phase identification crew uses the trace tone to identify and label the phase on each of the conductors. This is repeated for each set (3 conductors) of cable ends that need to be spliced. In the case of medium voltage transmission cables, the transformers are located a distance from the location of the failure. It is time consuming for the phase identification crew to travel, set up to enter an underground structure to perform the splice, and then perform the testing required to establish the phases. In addition, multiple trips may be required. This is performed for each set of cable ends (a minimum of two).

Once the conductors are labeled, the Splicer may complete the repair and splice the conductors on either side of the open circuit section back together. The power lines may then be re-energized and electrical service restored.

Accordingly, while the process for identifying and repairing conductors any three-phase system is suitable for its intended purposes the need for improvement remains, particularly in allowing the identification of electrical phase for a variety of cable types.

### BRIEF DESCRIPTION OF THE INVENTION

According to one aspect of the invention, a system for identifying an electrical phase of three conductors in a three-phase electrical system at an open end is provided. The system includes a transmitter and a receiver unit. The transmitter unit has three current transformers configured to removably couple with one of the three conductors adjacent the transformer. The transmitter unit further having a first communication device configured to transmit a phase identification signal indicating at least one electrical phase detected on one of the three conductors. The receiver unit has a first output lead configured to removably couple at the open end with a first conductor and a second output lead configured to couple with a second conductor. The receiver unit is configured to transmit a trace current onto the first output lead. The receiver further displays phase identification information in response to receiving the phase identification signal.

It should be appreciated that while embodiments herein describe the system 100 in connection with a three-phase electrical distribution or transmission system, this is for the exemplary purposes and the claimed invention should not be so limited. Embodiments of the present invention may include three or more electrical phases or may also include multiple three-phase circuits arrange in parallel for example.

According to another aspect of the invention, a method of identifying the electrical phase of three conductors in a three-phase electrical system is provided. The electrical conductors having a first end coupled to a transformer and a second open end. The method includes coupling three current transformers to the three conductors adjacent the transformer. A first output lead is coupled a first of the three conductors at the open end and a second output lead at a second of the three conductors at the open end. A trace current is transmitted with the first output lead onto the first conductor. The trace current is detected with at least one of the current transformers. A phase identification signal is transmitted with a transmitting unit coupled to the three current transformers. The phase identification signal is received with a receiving unit coupled to the first output lead and the second output lead. Cable phase identification information is displayed on the receiving unit in response to receiving the signal.

According to yet another aspect of the invention, a system for identifying an electrical phase of conductors in a three-phase electrical system at an open location between and distal from a first transformer and a transformer is provided. The system includes a first transmitter unit, a second transmitter unit and a receiver. The first transmitter unit has three current transformers, each of the three current transformers being configured to removably couple with one of the three conductors adjacent the first transformer, the first transmitter unit further having a first communication device configured to transmit a first phase identification signal indicating at least one electrical phase detected on one of the three conductors. The second transmitter unit has three current transformers, each of the three current transformers being configured to removably couple with one of the three conductors adjacent the second transformer, the second transmitter unit further having a second communication device configured to transmit a second phase identification signal indicating at least one electrical phase detected on one of the three conductors. The receiver unit includes a first output lead configured to removably couple at the open location with a first conductor coupled to the first transformer and a second output lead configured to removably couple at the open location with a second conductors coupled to the first conductor. The receiver unit also includes a third output lead configured to removably couple at the open location with a third conductor coupled to the second transformer and a fourth output lead configured to removably coupled at the open location with a fourth conductor coupled to the second transformer. The receiver unit is configured to transmit a trace current onto the first output lead and the third output lead, the receiver unit having a second communications device configured to couple for communication with the first communications device and the second communication device, the receiver having a display electrically coupled to the second communications device to display information in response to receiving the first phase identification signal and the second phase identification signal.

These and other advantages and features will become more apparent from the following description taken in conjunction with the drawings.

### BRIEF DESCRIPTION OF THE DRAWING

The subject matter, which is regarded as the invention, is particularly pointed out and distinctly claimed in the claims at the conclusion of the specification. The foregoing and other features, and advantages of the invention are apparent from the following detailed description taken in conjunction with the accompanying drawings in which:

FIG. 1 is a perspective view of a phase receiver unit for a deadline phase identification system in accordance with an embodiment of an invention;

FIG. 2 is a perspective view of the phase transmitter unit for a deadline phase adaptation system in accordance with an embodiment of an invention;

FIG. 3 is another perspective view of the phase transmitter of FIG. 2;

FIG. 4 is another perspective view of the phase receiver of FIG. 1 with output cables connected;

FIG. 5 is a schematic view of the deadline phase a identification system in accordance with an embodiment of the invention;

FIG. 6 is another schematic view of the deadline phase identification system in accordance with an embodiment of the invention;

FIGS. 7-13 illustrate display windows for the phase receiver of FIG. 1;

FIGS. 14-16 illustrate display windows for the transmitter unit of FIG. 2;

FIG. 17 illustrates status messages shown on the display of the phase transmitter of FIG. 1;

FIG. 18 is a partial perspective view illustrating the connection of cable ends to the tracing current connectors on rubber cables;

FIGS. 19-23 illustrate the display window of the receiver unit of FIG. 2 during operation;

FIGS. 24-30 illustrate status displays in accordance with an embodiment of the invention;

FIG. 31 is a display window illustrating a frequency waveform;

FIG. 32 illustrates the connection of the current transformer to the phase transmitter unit;

FIGS. 33-34 illustrates the connection of current transformers to the cables at the transformer;

FIG. 35 is a perspective view illustrating the connection of lead cables to a transformer;

FIG. 36 is a perspective view illustrating the connection of current transformers to the lead cables at a transformer;

FIG. 37 is a perspective view illustrating the connection of current loops when phasing on terminated cables;

FIGS. 38-42 illustrate display windows of the phase transmitter unit; and

FIG. 43 illustrates an exemplary display window of the phase receiver unit in accordance with an embodiment of the invention.

The detailed description explains embodiments of the invention, together with advantages and features, by way of example with reference to the drawings.

### DETAILED DESCRIPTION OF THE INVENTION

Embodiments of the present invention provide advantages in allowing the identification of electrical phases in a three-phase system where the cable end is remotely located from a transformer. Embodiments of the present invention provide further advantages in allowing the identification of electrical phases for a variety of electrical cable types including but not limited to paper insulated lead covered cable, solid dielectric cable, oil filled pipe type cable or gas-filled insulated cable. Embodiments of the present invention provides still further advantages in allowing identification of electrical phases without having a direct electrical connection at the transformer.

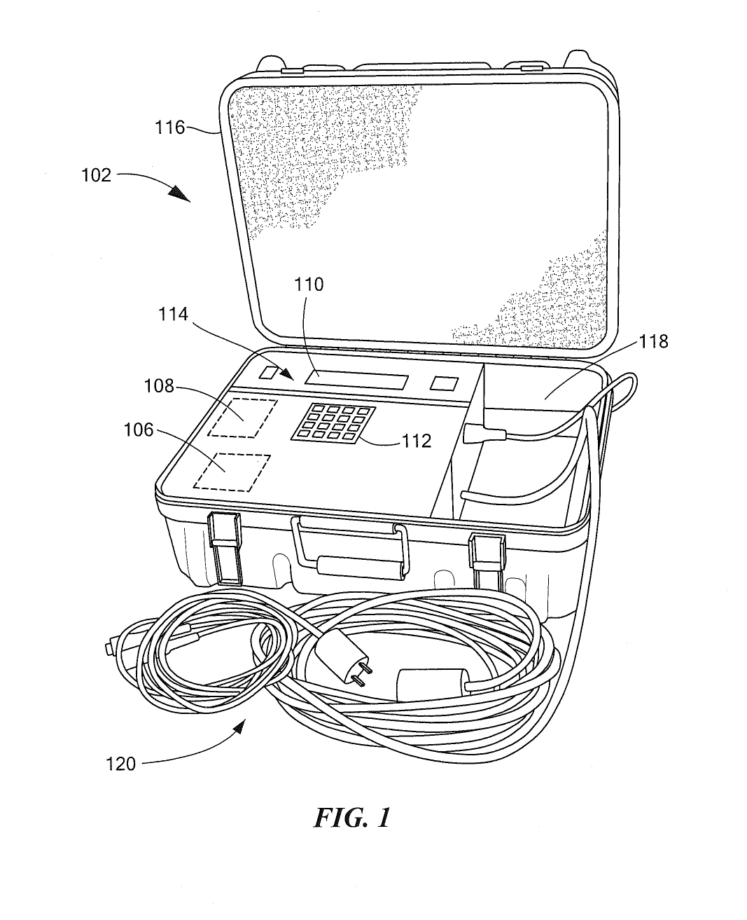

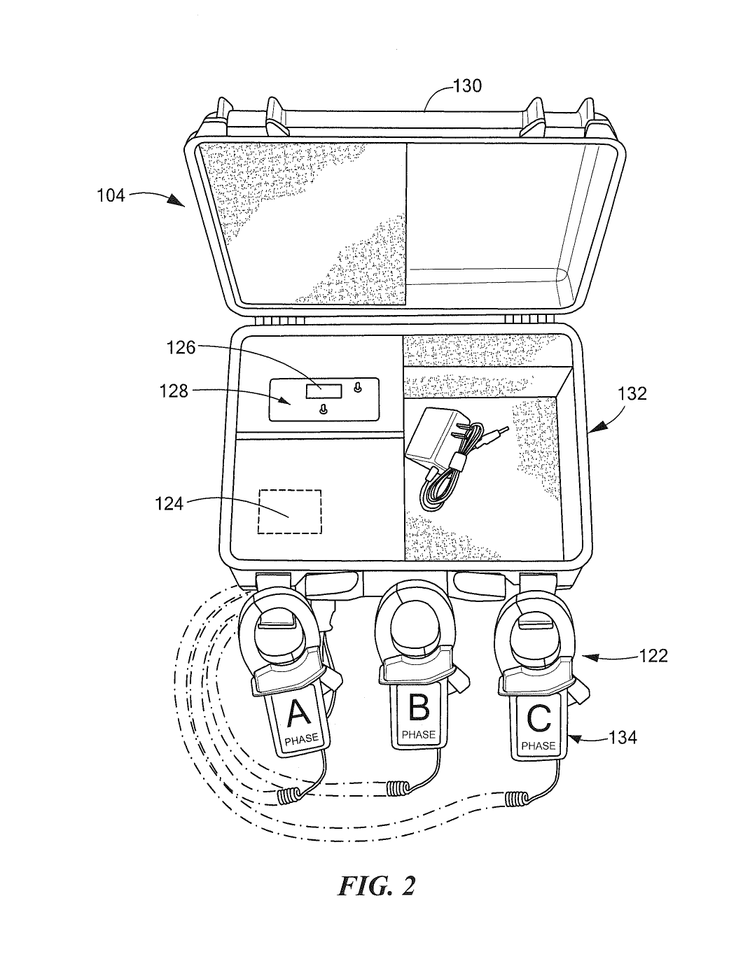

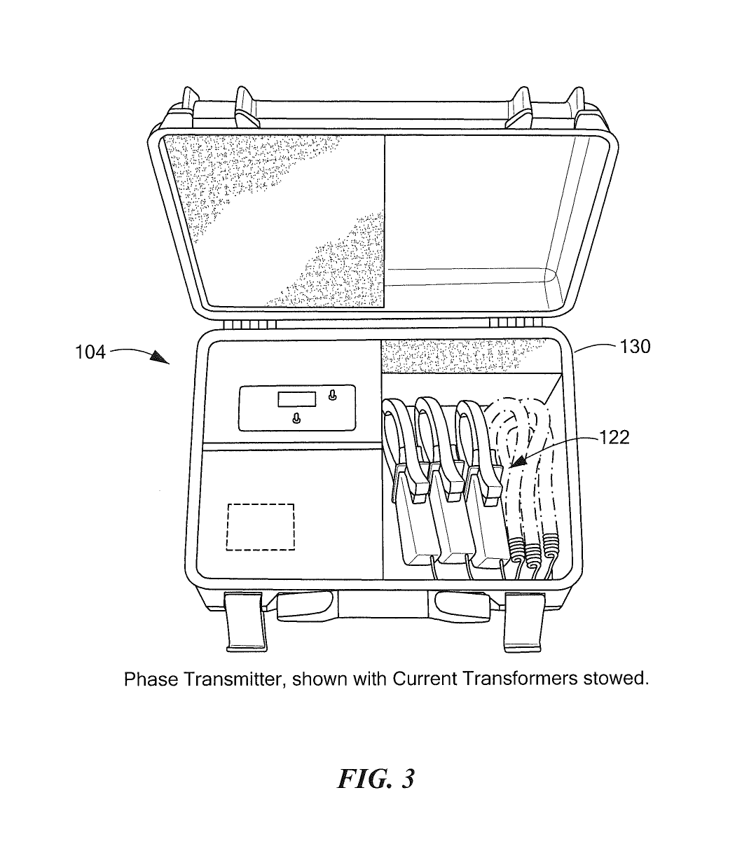

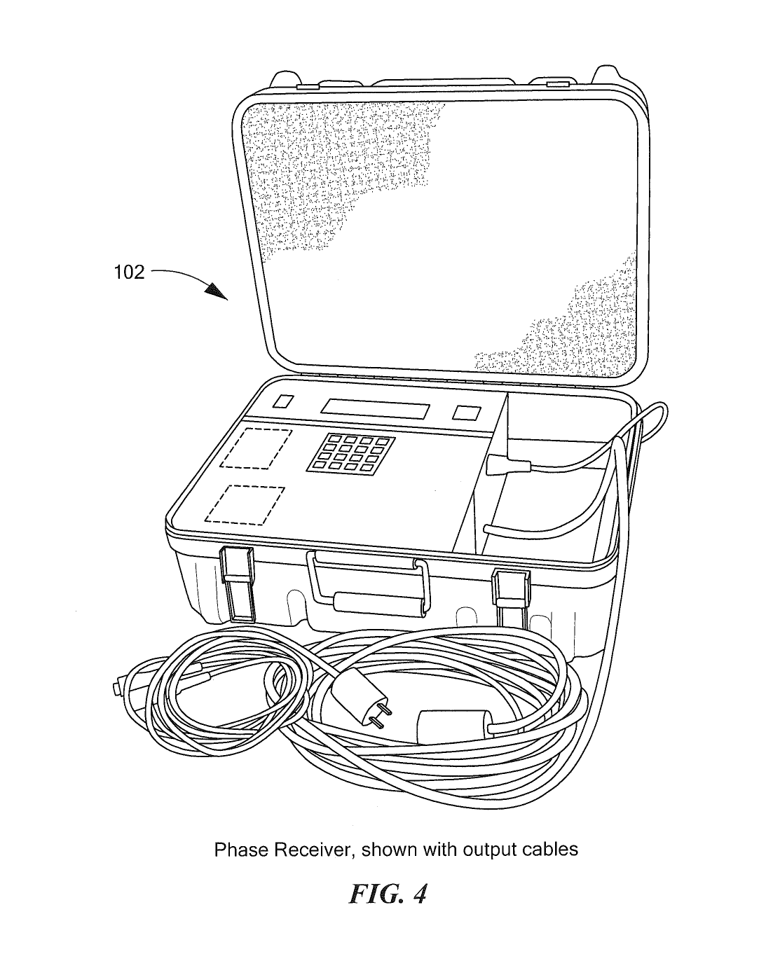

In the exemplary embodiment, a deadline phase identification system 100 is provided having a phase receiver unit 102 (FIG. 1) and the phase transmitter unit 104 (FIG. 2). The phase receiver unit 102 includes a tracing current output circuit 106, a cellular modem 108 and an LCD display 110. A keypad 112 is provided to change information shown on the LCD display 110 and three LED lamps 114 indicate system operation. The phase receiver unit 102 is contained within a case 116 that includes an area 118 size to allow the tracing current output leads 120 to be stored.

In one embodiment, the phase receiver unit 102 uses electrical power from an external source, such as line power, from a generator or from an inverter. In one embodiment the phase receiver unit 102 operates at 120 VAC at 3 A during operation. The phase receiver unit 102 is configured to transmit a tracing current via the output leads 120. In one embodiment the tracing current is limited to 9 V or less and may have a tracing current range from 0.1 to 9.0 amps depending on the impedance of the cables under test. The phase receiver unit 102 may include a cable having a NEMA L1-15 twistlock receptacle on one end that facilitates connecting the output leads 120 to the phase receiver unit 102. The output leads 120 may include alligator clips to facilitate connection with the cable being identified.

The phase transmitter unit 104 includes three current transformers 122, a cellular modem 124 and a battery that allows for remote operation. In LCD display 126 show system operation and status, while to toggle switches 128 allow for changes in the system operation to be made. The phase transmitter unit 104 is contained within a case 130 that includes an area 132 sized to receive and store the current transformers 122. Each of the current transformers 122 includes indicia 134 indicating the phase for that particular current transformer 122. It should be appreciated that while embodiments herein describe the communications between the phase transmitter unit 104 and the phase receiver unit 102 as being cellular communications, this is for exemplary purposes and the claimed invention should not be so limited. Embodiments of the invention may use other forms of communication, including but not limited to wireless, wired, wide-area computer networks, local-area computer networks, and radio for example.

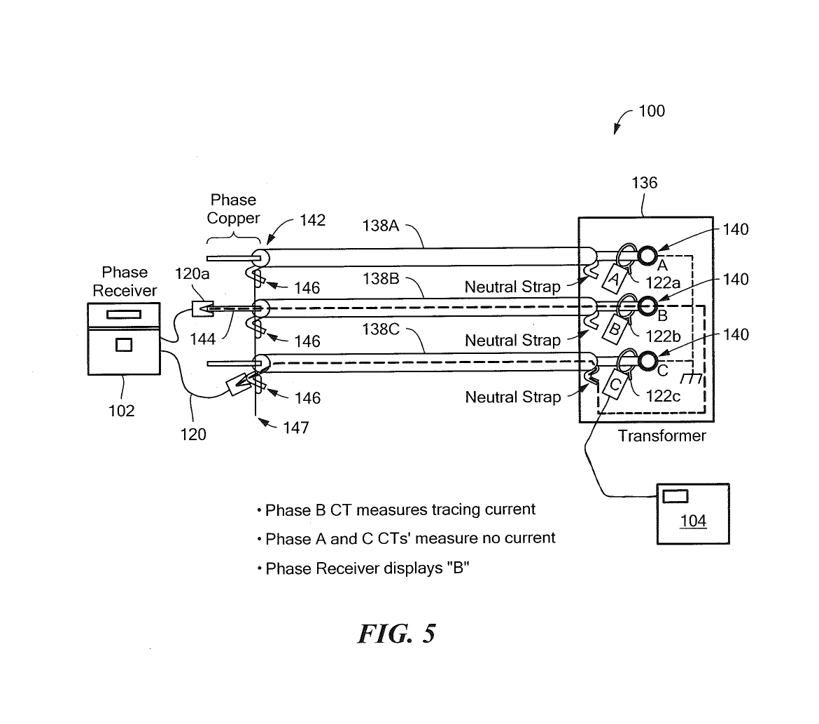

Referring now to FIG. 5 embodiment of the deadline phase identification system 100 is shown in a rubber cable application. In this embodiment, the system 100 is operated in a rubber cable mode that determines which of the set of three cables has tracing current impressed upon them. It should be appreciated that when this determination is made the end of the cable can be correctly marked with the desired phase identification. It should further be appreciated that any electrical cable using rubber, XLP, plastic, EDPM or any other nonconductive outer insulation layer may have the electrical phases identified using this rubber cable mode.

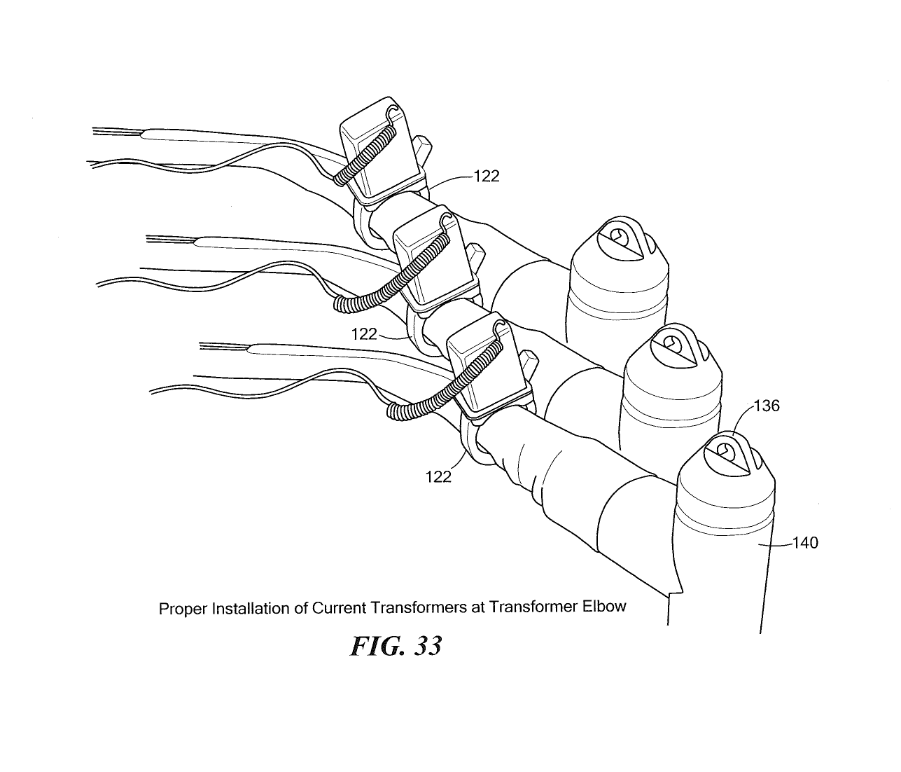

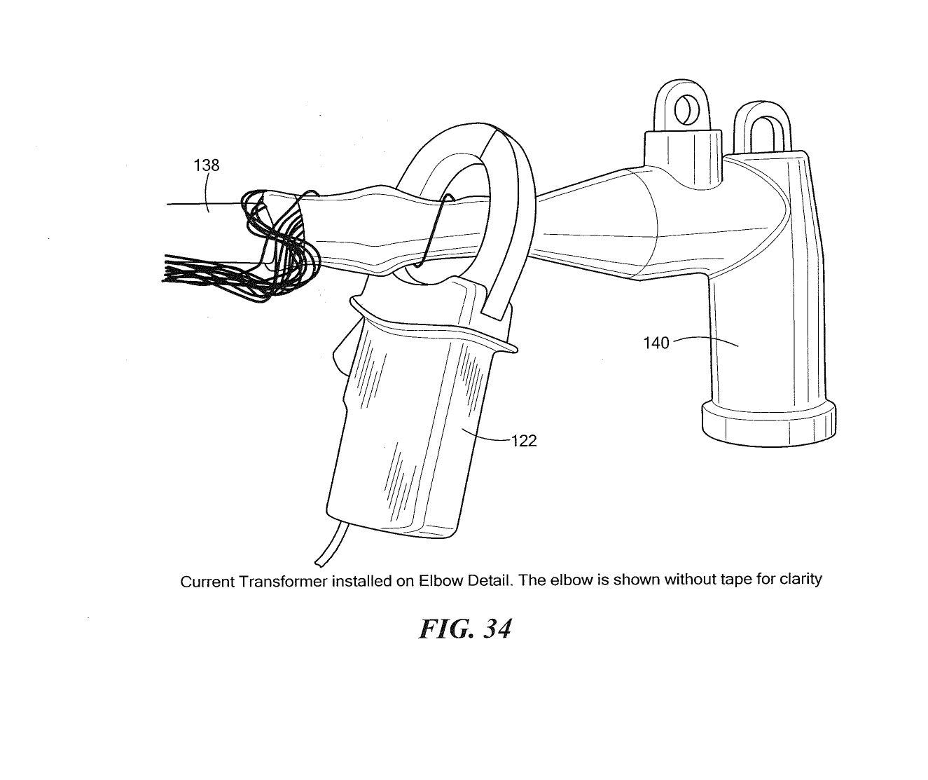

The transmitter unit 104 is positioned adjacent a transformer 136 that is located opposite the open end 142 of electrical cables 138. Each of the current transformers 122 are coupled to one of the cables 138 adjacent the transformer elbows 140 (FIGS. 33-34). It should be appreciated that the respective electrical phase for each of the cables 138 is known at the transformer 136 and the current transformers 122 are matched with the cable 138 having the same electrical phase. Further, the transformer 136 internal ground is applied to allow for a loop of the tracing current to flow in each cable 138.

At the open end 142 of the cables the phase receiver unit 102 is positioned adjacent the end of the cables 138. A first output lead 120A is connected to the copper conductor 144 a first cable, such as cable 138B for example. A second output lead 120C is connected to the neutral strap 146 of a second cable, such as cable 138C for example. In one embodiment, the neutral straps 146 are connected together by a bond wire 147 (FIG. 37) A tracing current is transmitted by the phase receiver unit 102 onto the first output lead 128 and the copper conductor 144. Tracing current sent through the cable 138B and returns through the cables concentric neutral strap 146. This tracing current is detected by one of the phase transmitter unit 104 current transformers 122. The transmitter unit 104 then transmits via cellular modem 124 to the phase receiver unit 102 a signal that indicates the identity of the electrical phase that the trace current signal was detected on. The phase receiver unit 102 then displays the electrical phase identified by the phase transmitter unit 104 and the operator may label the cable that the first output lead 120 is connected to. This process is repeated for each of the cables 138 until the electrical phase for each of the cables is identified.

It should be appreciated that at the location of open-end 142 there will be two sets of cables that need to be identified on either side of the break. In one embodiment, a second transmitter unit 104 is located at a second transformer 136 and the electrical phase identification is performed on this second cable as well. After all of the cables have been identified in splicing operations have reconnected the ends of the cables, the tracing current may be applied once again. When this step is performed, each of the transmitter units 104 should transmit to the receiver unit 102 the same electrical phase identification to provide verification. In one embodiment, the identification process occurs simultaneously on each side of the open end 142.

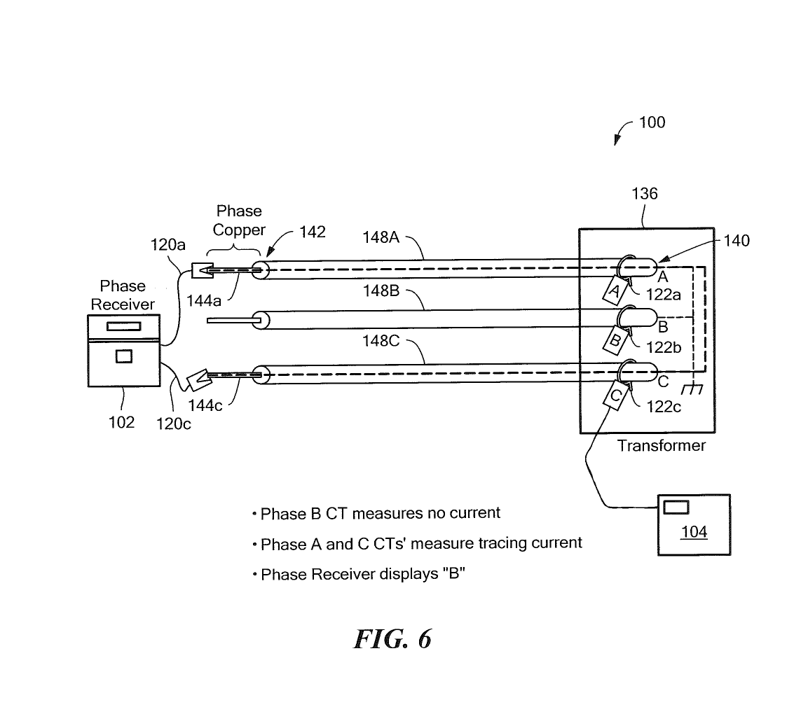

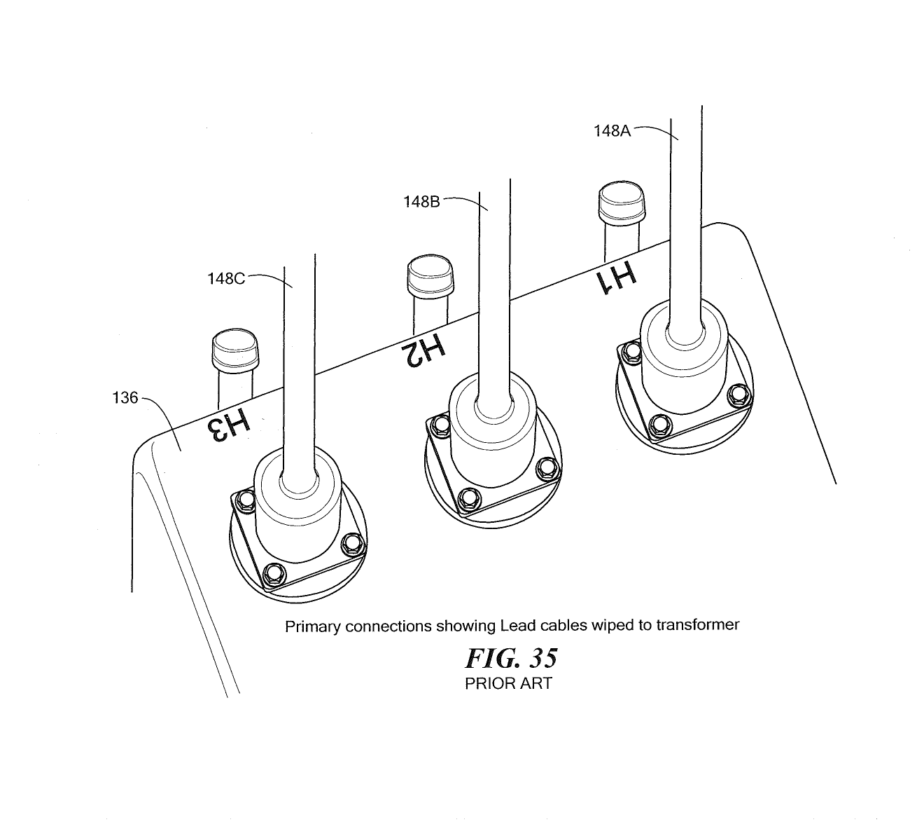

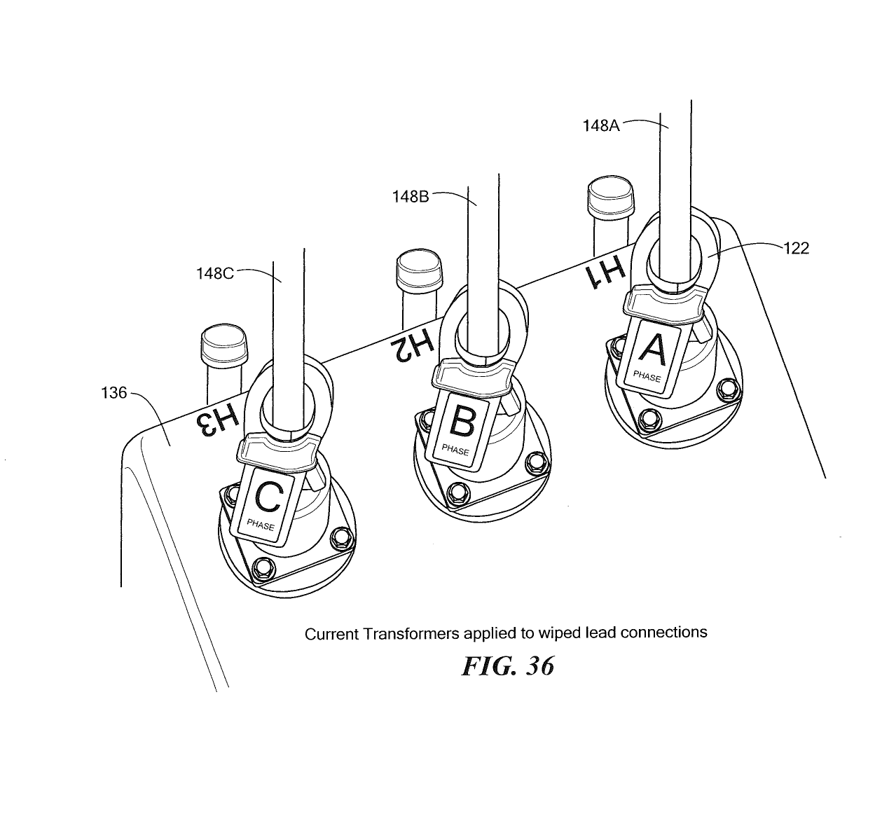

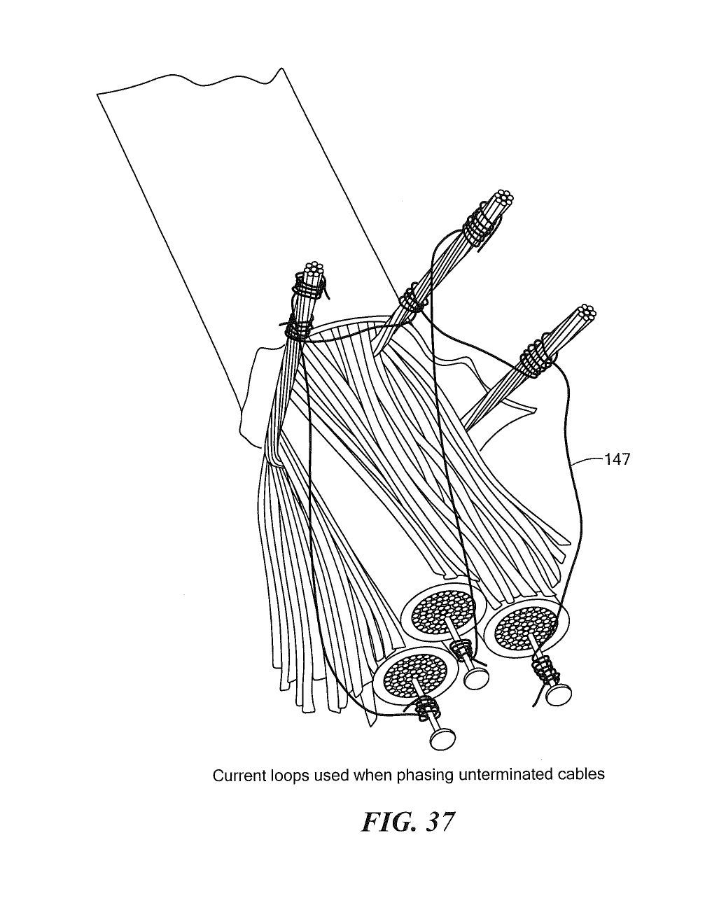

Referring now to FIG. 6 embodiment is shown of the deadline phase identification system 100 used with lead jacketed cables 148. It should be appreciated that this lead cable mode allows identification of electrical phases for any electrical cable having a conductive outer jacket, such as paper insulated lead covered cable or lead to cambric cable. In this embodiment, the transmitter unit 104 is once again positioned adjacent the transformer 136. Each of the current transformers 122 are coupled with their respective cable 148 adjacent the transformer elbow 140 (FIGS. 35-36). It should be appreciated that in applications using a conductive outer jacket, the outer jacket of the cable is electrically connected to the transformer and the neutral straps do not allow the tracing current to be carried back to the open-end and 42. The transformer 136 internal ground is applied to make a loop for tracing current to flow and each cable 148. Therefore to form a loop for the tracing current to flow two electrical phases are used.

As before, the receiver unit 102 is positioned adjacent the open-end 142. The first output lead 120A is connected to the copper conductor 144A of a first cable, such as cable 148A. In this embodiment the second output lead 120C is connected to the copper conductor 144C of the second cable, such as cable 148C. The tracing current is then applied via first output lead 120A and received back through second output lead 120C. The tracing current is detected via the current transformers 122 by the transmitter unit 104. The phase transmitter unit 104 having detected the tracing current on cables 148A, 148C then transmits this electrical phase identification to the phase receiver unit 102. The phase receiver unit 102 then displays the electrical phase of the unconnected cable 148B. The operator may then label the cable to which the output leads 120A, 120C are not connected. This process is repeated for each of the cables 148 until the electrical phase for each of the cables is identified.

As discussed above, it should be appreciated that at the location of open-end 142 there will be two sets of cables that need to be identified on either side of the break. In one embodiment, a second transmitter unit 104 is located at a second transformer 136 and the electrical phase identification is performed on this second cable as well. After all of the cables have been identified in splicing operations have reconnected the ends of the cables, the tracing current may be applied once again. When this step is performed, each of the transmitter units 104 should transmit to the receiver unit 102 the same electrical phase identification to provide verification.

It should be appreciated that the transformer 136 ground remains applied while the phase measurements are made. This provides advantages in maintaining a desired electrical ground to protect repair personnel.

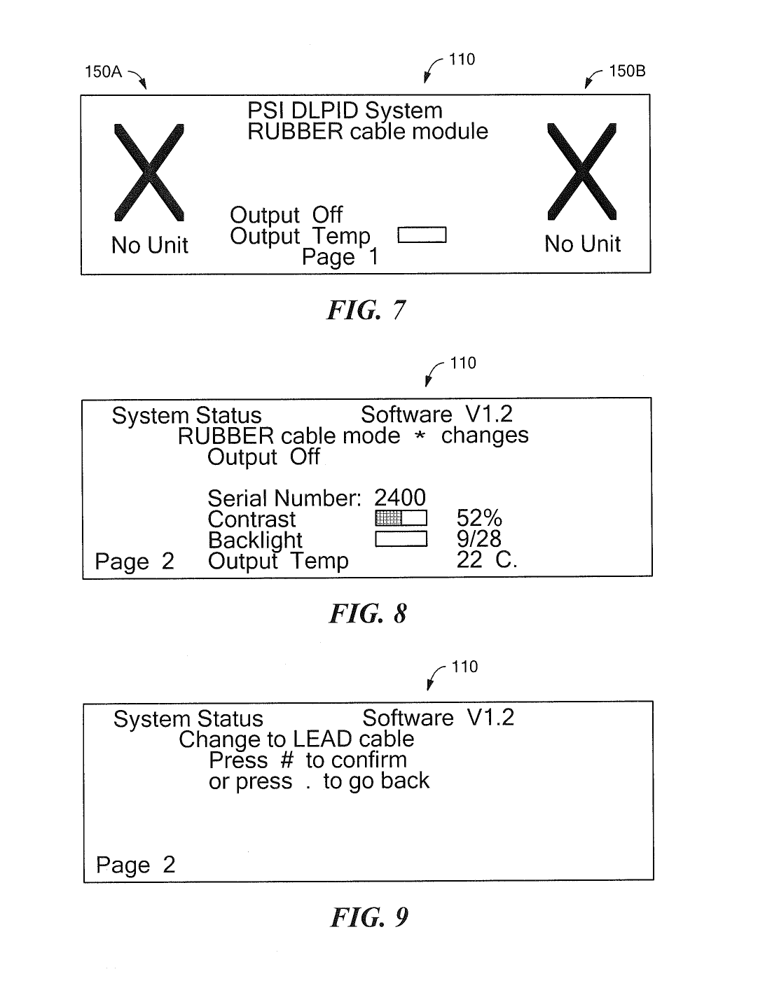

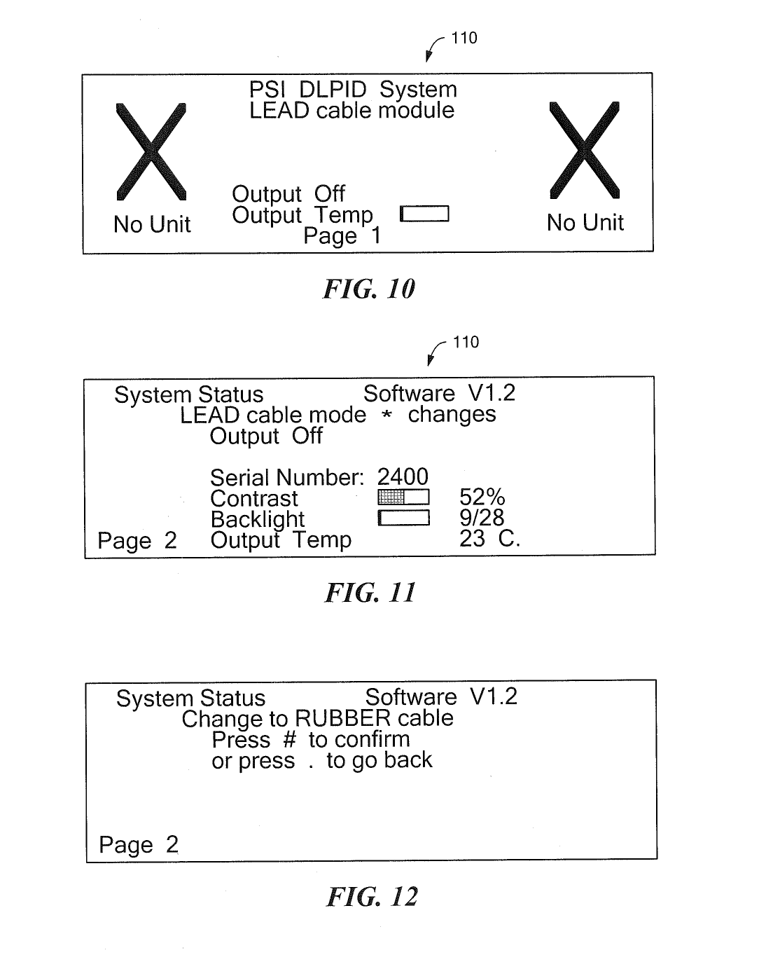

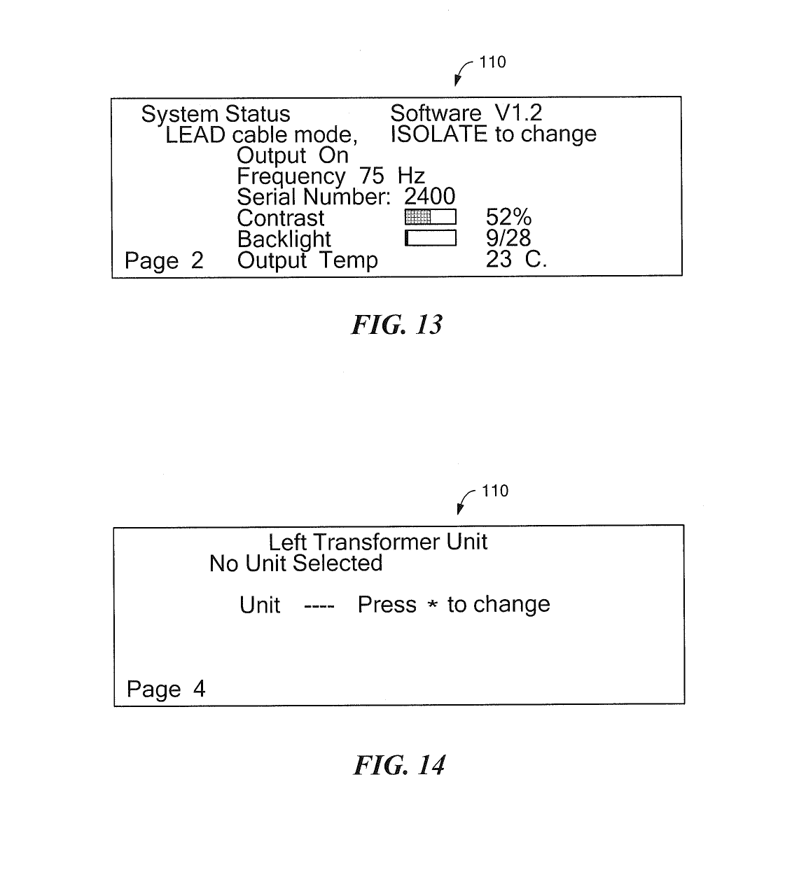

During the initial setup of the system 100, the receiver unit 102 is first connected with electrical power and a run/isolate switch is moved to the isolate position. The receiver unit 102 is turned on and a cellular modem is activated. The display 110 shows an initial display such as that shown in FIG. 7 indicating the overall status. The operator then selects the mode of operation (rubber cable or lead), in the exemplary embodiment the receiver unit defaults to rubber cable mode. The mode of operation is shown on the display, as shown in FIGS. 8-12. In one embodiment, the receiver unit 102 needs to have the run/isolate switch in the isolate position in order to change modes. In this embodiment, the display 110 may indicate this to the operator as shown in FIG. 13.

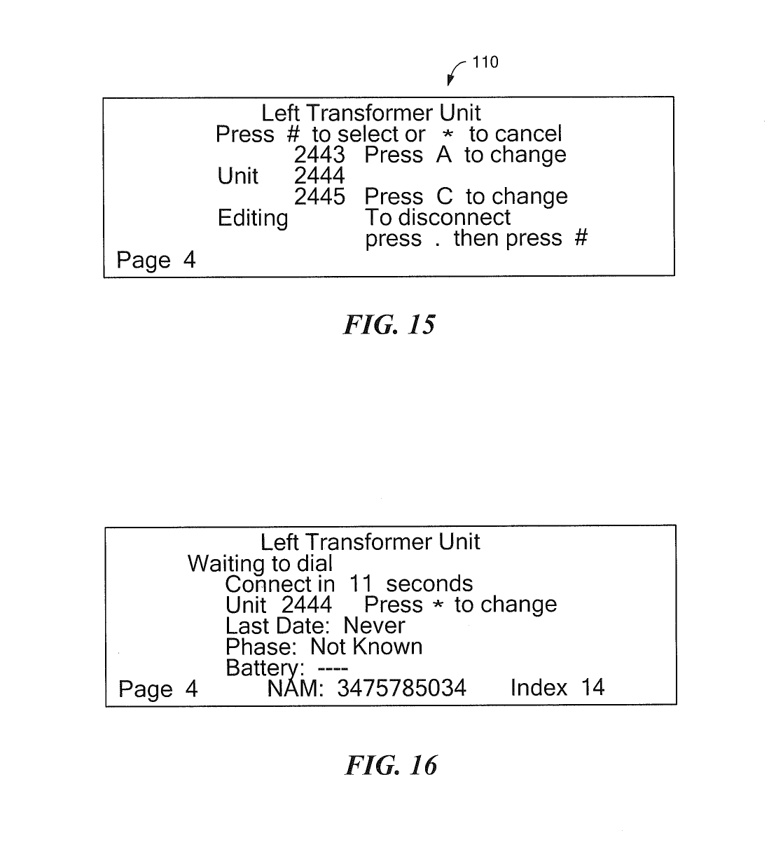

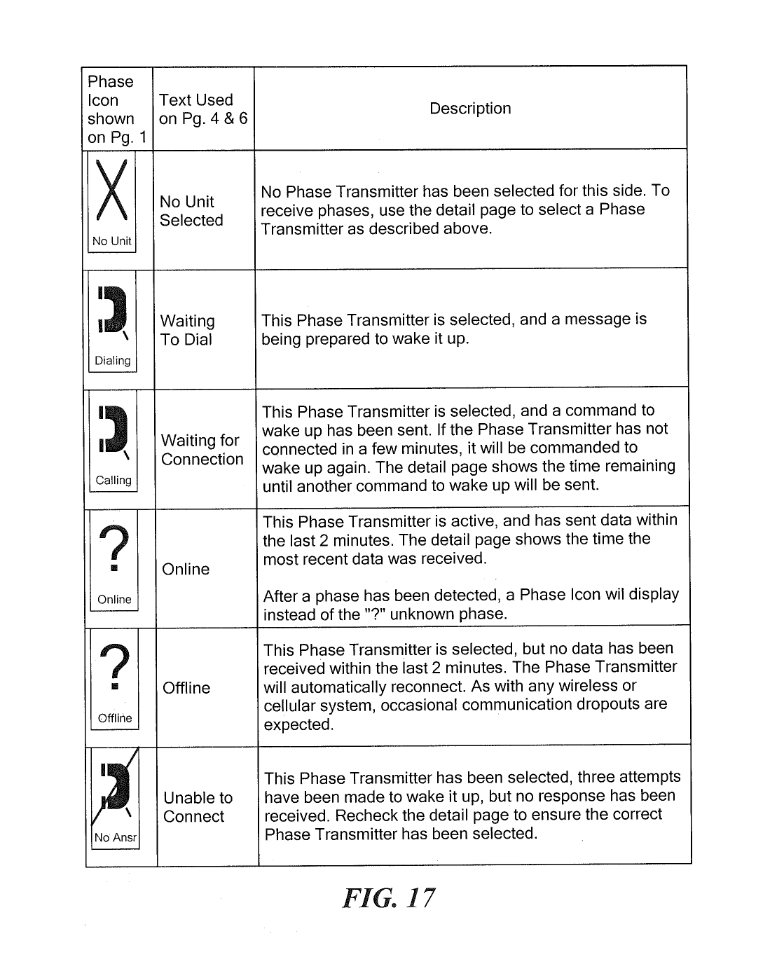

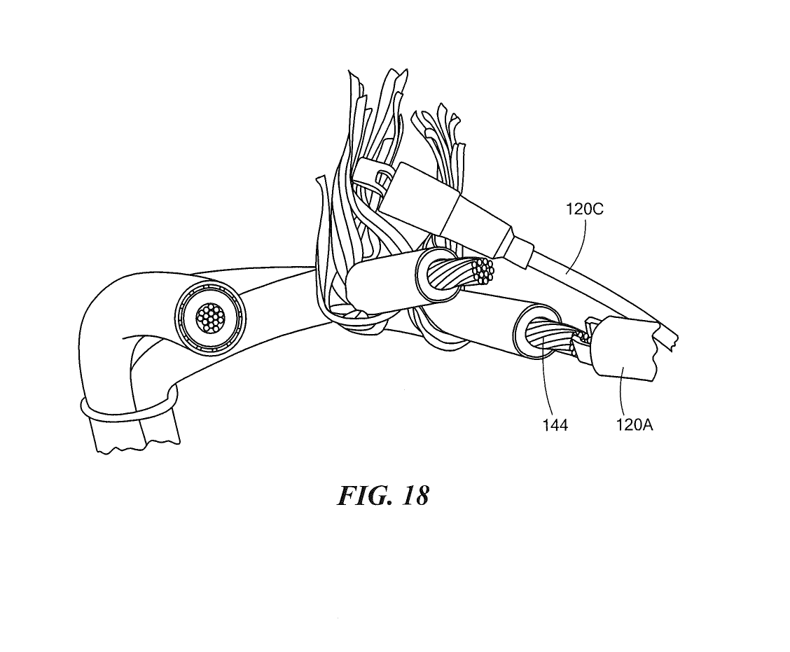

Next, the identification parameters of the transmitter unit(s) 104 that determined and entered into the receiver unit 102. This may be done, for example, by entering the serial number of the transmitter unit(s) 104 as shown in FIGS. 14-16. It should be appreciated that were multiple transmitter units 104 used, the display 110 may indicate these on different areas 150A, 150B of the display 110. These areas 150A, 150B are used to indicate the status of each phase transmitter unit 104. In one embodiment, these areas 150A, 150B use icons, such as those shown in FIG. 17 for example, to indicate status.

Where operation is being performed on a rubber coated cable, the alligator clip for the lead 120A is connected to the copper conductor 144. In some applications a copper nail (FIG. 37) may be used to facilitate the connection of the alligator clip to the copper conductor 144. This avoids having to strip back the insulation on the conductor. The alligator clip on lead 120C is connected to the cables concentric neutral strap. In one embodiment, the concentric neutral straps of the cables are connected together to improve the loop for tracing currents to flow.

During operation performed on a lead coated cable this process is similar except that the second lead 120C is connected to the copper conductor on the second cable as described above. In both modes of operation the run/isolate switch is changed to the isolate position prior to moving the alligator clip between cables. This interrupts the tracing current and indicates to the phase receiving unit 102 that the operator is moving the output lead 122 different cable. At the transformer, the loop is completed by moving the transformer primary ground lever to the “ground” position. If the phasing cables are not yet terminated at the transformer 136, the copper conductors and neutral straps (for rubber coated cables) may be connected together with temporary wires.

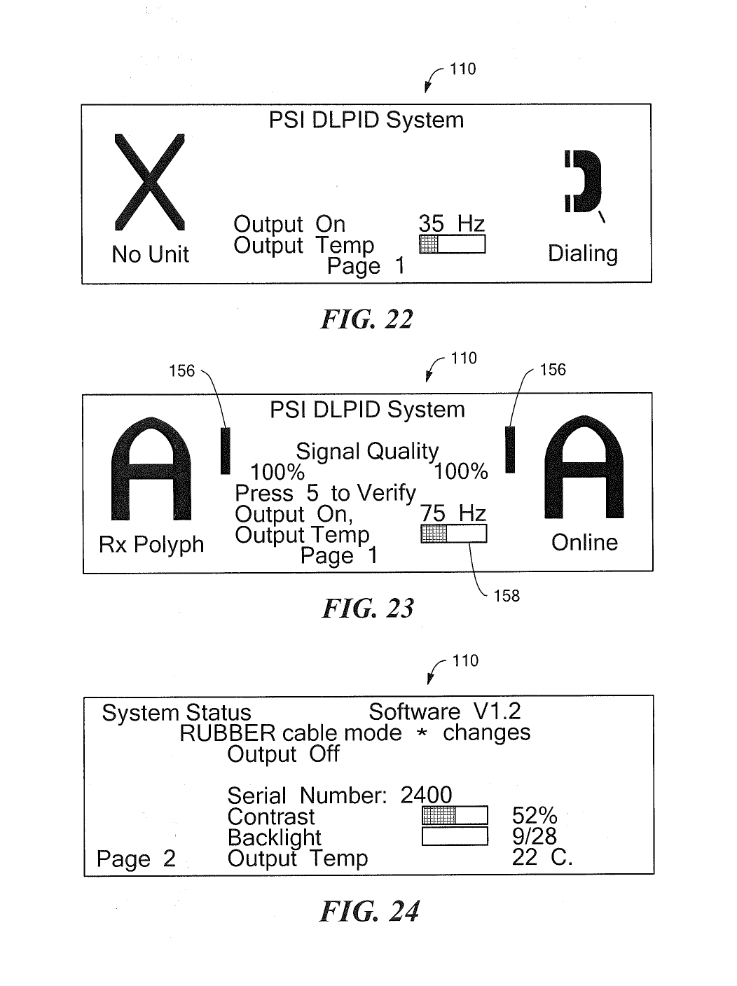

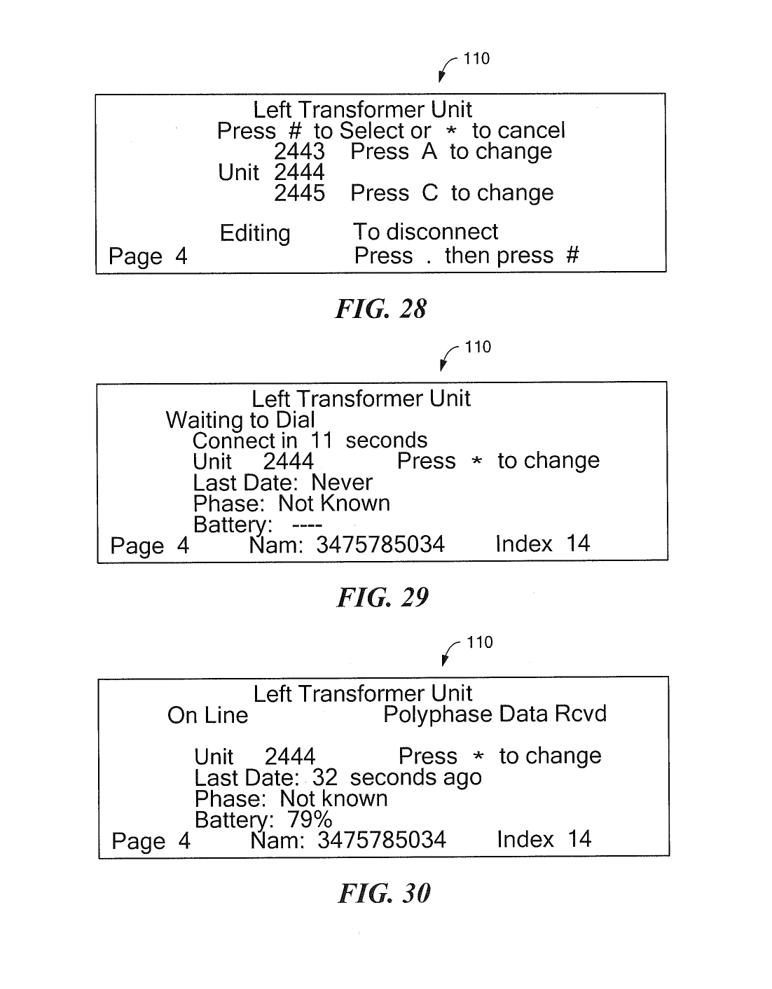

In the exemplary embodiment, the phase receiving unit 102 will automatically receive the identified phases from each phase transmitter unit 104 until the tracing current is removed. If the receiving unit 102 and the transmitting unit 104 are not connected for communication, the display 110 will indicate a “phone symbol” as shown in FIG. 22. During this initiation procedure during startup, the display 110 may include information such as that shown in FIGS. 27-30 which allow the operator to identify the desired transmitter units 104.

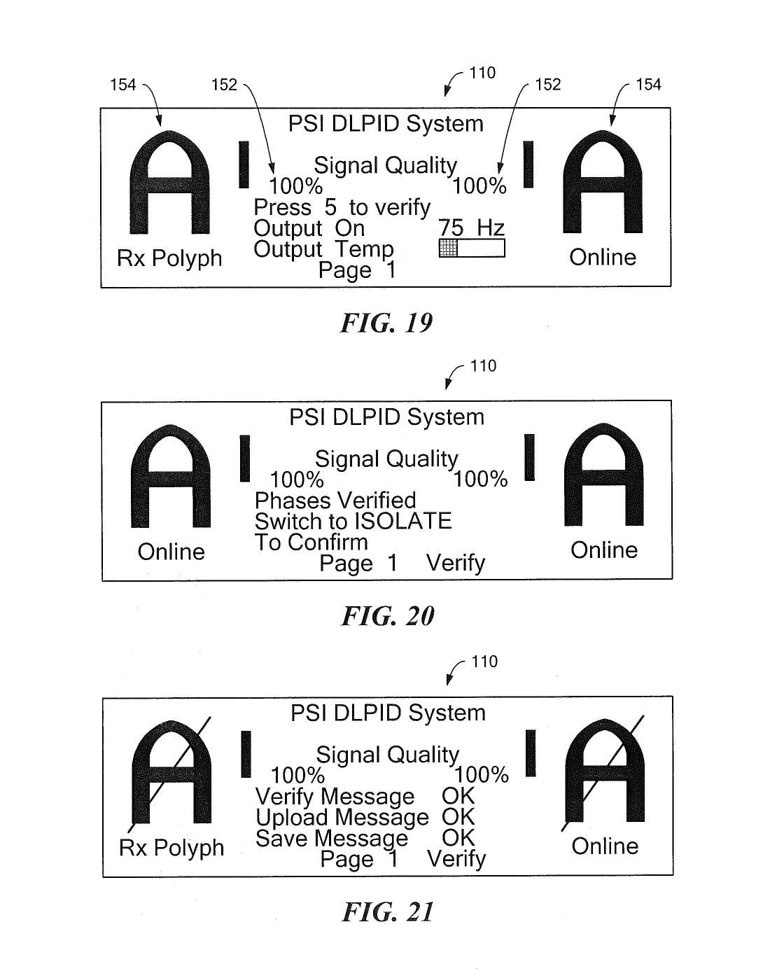

In an embodiment, the display 110 indicates a signal quality 152 which indicates that more verifications of the displayed phase have been made. In one embodiment four phase measurements are made in order to get a 100% signal quality. As shown in FIG. 19, the display 110 will indicate the phase identification transmitted by the phase transmitter unit 104. The displayed icon 154 may indicate “A”, “B” and “C” or “1”, “2” and “3” depending on the phase naming conventions of a particular electrical utility where the repair is being made. If the phase cannot be identified, the display 110 will show a “?” Icon. Once the phases have been verified, the display 110 will indicate to the operator to switch to the switch to the isolate position (FIG. 20) to confirm the identification. When in the switches in the isolate position, the phase icon will continue to be displayed with a diagonal line (FIG. 21).

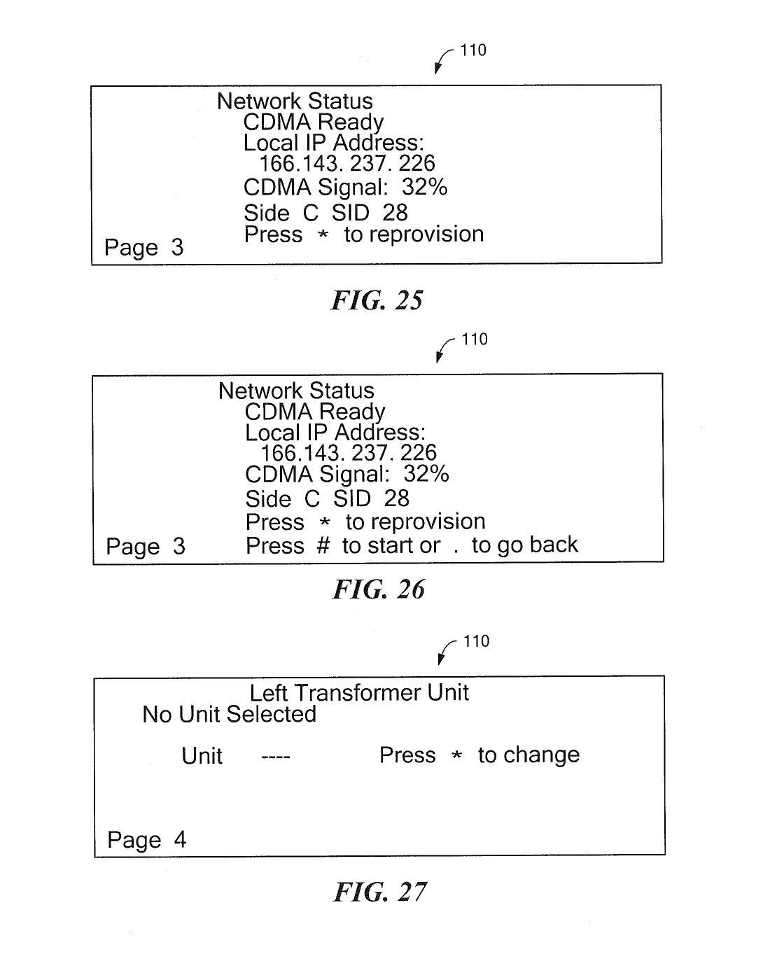

In one embodiment, when the phase transmitter unit 104 is online, a vertical bar graph symbol 156 is shown on display 110 as shown in FIG. 23. The display 110 may also include an indication 158 of the temperature of the output circuits. The display 110 may also include other information such as system status information shown in FIG. 24, the cellular modem status shown in FIGS. 25-26.

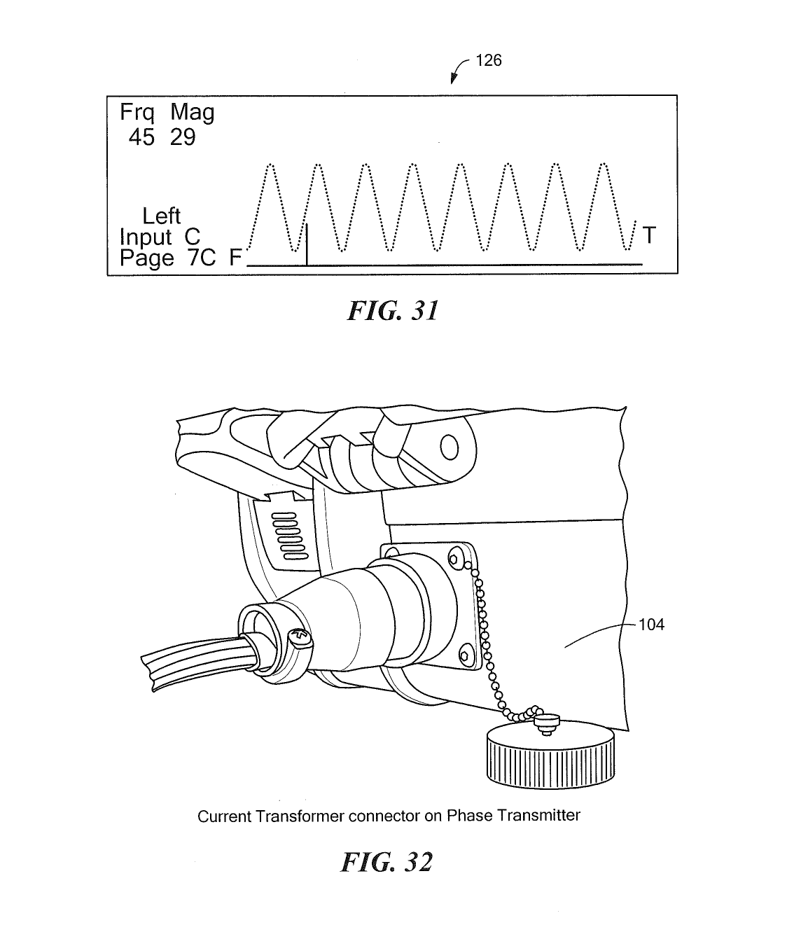

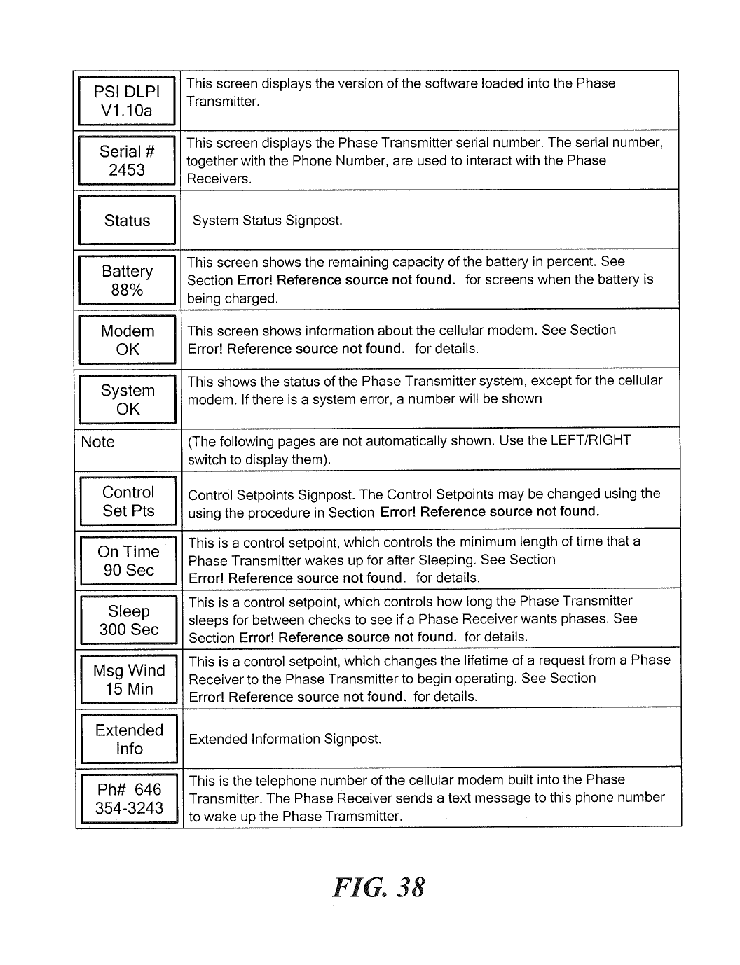

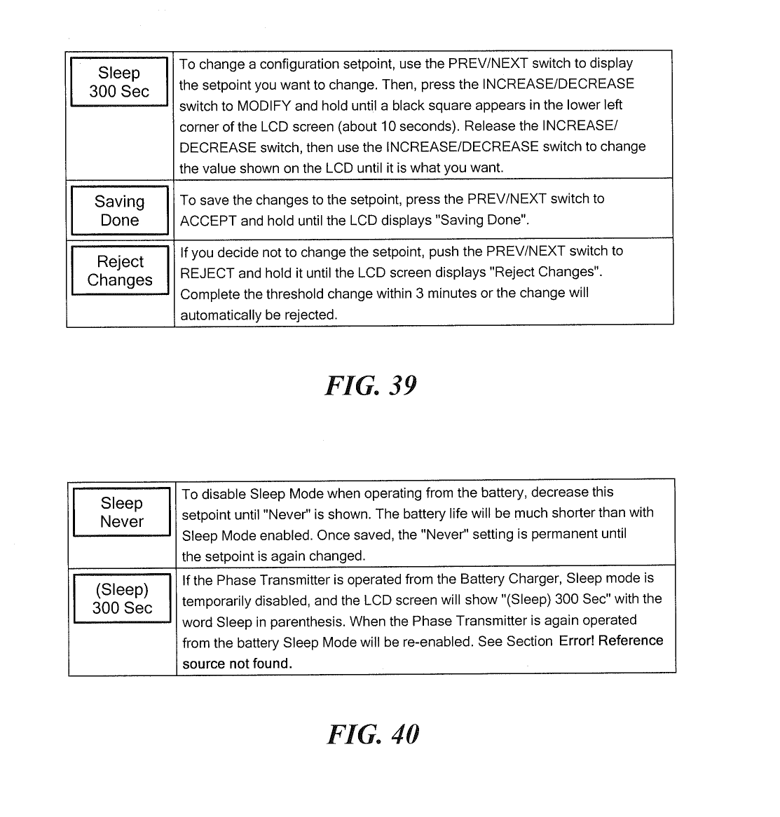

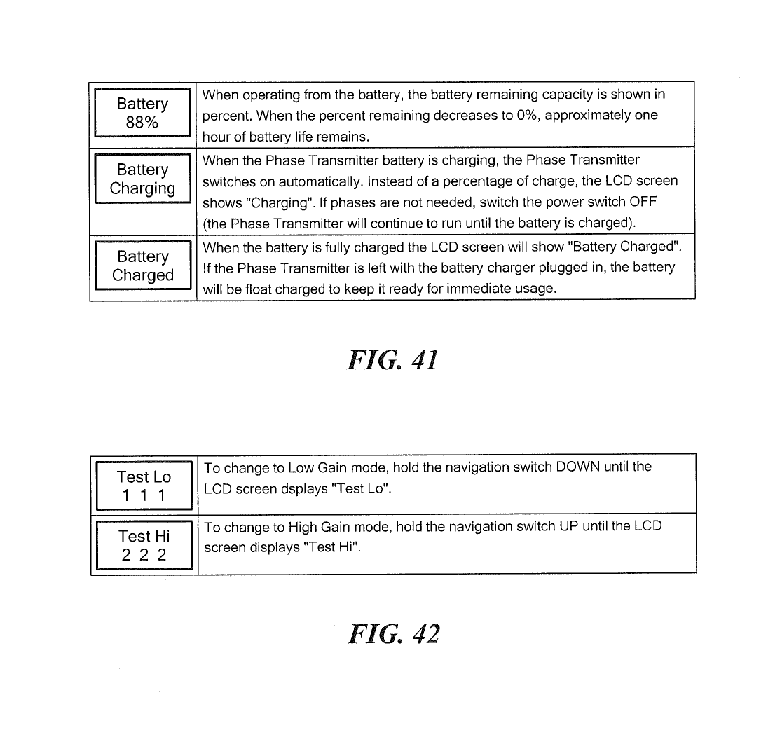

On the phase transmitter unit 104, the display 126 may be used to show the operators the signal being measured at each current transformer 122. In one embodiment, the display 126 shows the frequencies in the format of an oscilloscope waveform as shown in FIG. 31. The display 126 may further be used to indicate additional information as shown in FIGS. 38-42.

After the cables have been identified, the system 100 may include a phase verification record to document the splicing of the cables together. This phase verification record 160 may be automatically transmitted via cellular modem 106 to a remote computer for storage. In other embodiments, the phase verification record may be stored locally on the phase receiver unit 102 on removable media, such as a flash drive for example. In still other embodiments, the phase receiver unit 102 may include an output port such as but not limited to a USB port, an ethernet port or serial port for example that allows the phase receiver unit 102 to communicate data of the phase verification record 160 an external device. In still other embodiments, the phase receiver unit 102 may include a wireless connection circuitry including but not limited to Bluetooth or WiFi for example, to allow communication of the phase verification record 160.

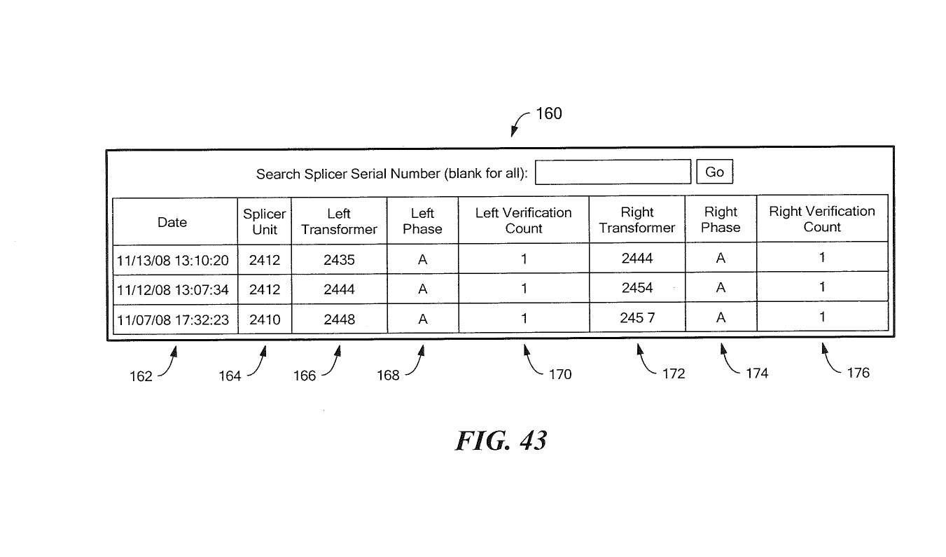

In one embodiment, the phase verification record 160 is shown in FIG. 43 in the form of a table. The phase verification record 160 may include records of the day in time 162, the serial number of the phase receiver unit 164, the serial number of the transmitter units 166, 172, the phase received 168, 174 and the verification counts 172, 176. In this way, and operators such as electrical utility can automatically document the repair.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

1. A system for identifying an electrical phase of three conductors in a three-phase electrical system, the electrical conductors having a first end coupled to a transformer and a second open end, the system comprising:
a first transmitter unit having three current transformers, each of the three current transformers being configured to removably couple with one of the three conductors adjacent the transformer, the first transmitter unit further having a first communication device configured to transmit a phase identification signal indicating at least one electrical phase detected on one of the three conductors; and
a receiver unit have a first output lead configured to removably couple with a first of the three conductors at the open end and a second output lead configured to couple with a second of the three conductors at the open end, the receiver unit being configured to transmit a trace current onto the first output lead, the receiver unit having a second communications device configured to couple for communication with the first communications device, the receiver having a display electrically coupled to the second communications device to display information in response to receiving the phase identification signal.

2. The system of claim 2 wherein the first output lead is configured to couple with a first copper conductor portion of the first conductor and the second output lead is configured to couple with a second copper portion of the second conductor.

3. The system of claim 2 wherein second output lead is further configured to couple with a neutral strap of the second conductor.

4. The system of claim 1 wherein the first phase identification signal includes a first phase identification data of the first conductor and a second phase identification data of the second conductor.

5. The system of claim 4 wherein the receiver unit is configured to display the phase identity of the third conductor in response to receiving the first phase identification data and the second phase identification data.

6. The system of claim 5 wherein the first communications device and the second communications device are cellular modems.

7. A method of identifying the electrical phase of three conductors in a three-phase electrical system, the electrical conductors having a first end coupled to a transformer and a second open end, the method comprising:
coupling three current transformers to the three conductors adjacent the transformer;
coupling a first output lead at a first of the three conductors at the open end and a second output lead at a second of the three conductors at the open end;
transmitting a trace current with the first output lead onto the first conductor;
detecting the trace current with at least one of the current transformers;
transmitting a phase identification signal with a transmitting unit coupled to the three current transformers;
receiving the phase identification signal with a receiving unit coupled to the first output lead and the second output lead; and
displaying cable phase identification information on the receiving unit in response to receiving the signal.

8. The method of claim 7 further comprising:
coupling the first output lead to a first copper portion of the first conductor; and
coupling the second output lead to a second copper portion of the second conductor.

9. The method of claim 8 wherein the phase identification signal includes a first phase identification data of the first conductor and a second phase identification data of the second conductor.

10. The method of claim 9 further comprising displaying the phase identification of the third conductor in response to receiving the first phase identification data of the first conductor and the second phase identification data.

11. The method of claim 7 further comprising coupling the second lead to a neutral strap.

12. The method of claim 11 wherein the phase identification signal includes a first phase identification data of the first conductor.

13. The method of claim 12 further comprising displaying the phase identification of the first conductor in response to receiving the first phase identification data.

14. The method of claim 13 further comprising coupling the first output lead to a third copper portion of the third conductor and displaying the phase identification of the third conductor in response to receiving the phase identification signal.

15. A system for identifying an electrical phase of conductors in a three-phase electrical system at an open location between and distal from a first transformer and a transformer, the system comprising:
a first transmitter unit having three current transformers, each of the three current transformers being configured to removably couple with one of the three conductors adjacent the first transformer, the first transmitter unit further having a first communication device configured to transmit a first phase identification signal indicating at least one electrical phase detected on one of the three conductors;
a second transmitter unit having three current transformers, each of the three current transformers being configured to removably couple with one of the three conductors adjacent the second transformer, the second transmitter unit further having a second communication device configured to transmit a second phase identification signal indicating at least one electrical phase detected on one of the three conductors; and
a receiver unit comprising:
a first output lead configured to removably couple at the open location with a first conductor coupled to the first transformer and a second output lead configured to removably couple at the open location with a second conductors coupled to the first conductor,
a third output lead configured to removably couple at the open location with a third conductor coupled to the second transformer and a fourth output lead configured to removably coupled at the open location with a fourth conductor coupled to the second transformer; and
the receiver unit being configured to transmit a trace current onto the first output lead and the third output lead, the receiver unit having a second communications device configured to couple for communication with the first communications device and the second communication device, the receiver having a display electrically coupled to the second communications device to display information in response to receiving the first phase identification signal and the second phase identification signal.

16. The system of claim 15 wherein:
the first output lead is configured to couple with a first copper conductor portion of the first conductor and the second output lead is configured to couple with a second copper portion of the second conductor; and
the third output lead is configured to couple with a third copper conductor portion of the third conductor and the fourth output lead is configured to couple with a fourth copper portion of the fourth conductor.

17. The system of claim 15 wherein second output lead are further configured to couple with a first neutral strap of the second conductor and the fourth output lead is configured to couple with a second neutral strap of the fourth conductor.

18. The system of claim 15 wherein:
the first phase identification signal includes a first phase identification data of the first conductor and a second phase identification data of the second conductor; and
the second phase identification signal includes a third phase identification data of the third conductor and a fourth phase identification data of the fourth conductor.

19. The system of claim 18 wherein the receiver unit is configured to:
display the phase identity of the fifth conductor coupled to the first transformer in response to receiving the first phase identification data and the second phase identification data; and
display the phase identity of a sixth conductor coupled to the second transformer in response to receiving the third phase identification data and the fourth phase identification data.

20. The system of claim 19 wherein the phase identity of the fifth conductor and the phase identity of the sixth conductor is displayed at the same time.
